(19) United States
(12) Patent Application Publication
(10) Pub. No.: US 2026/0112575 A1
(43) Pub. Date: Apr. 23, 2026

(54) Chamber with Grounded Ion Filter for Enhanced Atomic Layer Etching Processes for High Aspect Ratio Structures

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 18/920,853

(22) Filed: Oct. 19, 2024

(51) Int. Cl. H01J 37/32

(52) U.S. Cl. CPC H01J 37/321; H01J 37/32091; H01J 37/32128; H01J 2237/3341; H01J 2237/3343

(57) ABSTRACT

A method and system for atomic layer etching (ALE) are disclosed, utilizing a single gas or gas mixture without gas exchanges throughout the process. The plasma process chamber features an inductively coupled plasma (ICP) section for generating neutrals and a capacitively coupled plasma (CCP) section for ion-burst sputtering, separated by a grounded ion filter (GIF) that blocks ions while allowing neutrals and unreacted gases to pass. The system is optimized for forming high aspect ratio (HAR) structures.

### FIELD OF THE INVENTION

The present invention pertains to the field of semiconductor manufacturing, more specifically to atomic layer etching (ALE) techniques used in semiconductor device fabrication. The invention focuses on optimizing the ALE process by utilizing a single gas or a single gas mixture throughout the ALE process and designing process parameters to improve the ideality of the ALE process.

### BACKGROUND OF THE INVENTION

ALE has been developed to address the limitations of reactive ion etching (RIE), a widely used technique for material removal in semiconductor fabrication. Although RIE provides high etch rates and can handle a variety of materials, it suffers from significant drawbacks, particularly when applied to high aspect ratio (HAR) structures. These limitations include profile distortion and non-uniform etching. As semiconductor devices become more advanced, with increasing demands for smaller feature sizes and higher aspect ratios, these issues become more pronounced.

ALE offers a solution to these problems by enabling precise, atomic-scale material removal through sequential, self-limiting reactions. The ALE process typically comprises two steps: surface modification and material removal. During the surface modification step, chemically reactive neutrals—often generated in a plasma—modify the surface layer of the substrate, typically reducing the bond energy of a few monolayers. This step is followed by low-energy ion bombardment that removes the modified layer without damaging the underlying substrate. This sequence is repeated in cycles to achieve controlled, atomic-level etching.

While ALE provides significant advantages over RIE in terms of precision and selectivity, it presents its own set of challenges. The cyclic nature of ALE, with separate surface modification and material removal steps, inherently limits the etch rate, making it problematic for HAR structures where etch speed is critical. Conventional ALE processes often require gas exchanges between the surface modification and material removal steps, increasing cycle time and process complexity. ALE has not been widely adopted for etching deep HAR structures, such as channel holes in 3D NAND devices, primarily due to its slower etch rate. A method, described in U.S. Pat. No. 10,763,083 to Yang et al., employs high-energy ions to accelerate the removal of the modified layer and improve cycle time of the ALE.

Another challenge in ALE is the time required to generate ions with narrow energy distribution during the sputtering step which is critically important for etching HAR structures. In conventional ALE systems, substrate bias is applied using an RF power generator, which accelerates ions toward the substrate to remove the modified layer. However, RF power generators typically require tens of milliseconds to achieve the desired steady-state bias voltage. This delay can result in low speed for the removal step. Achieving rapidly consistent ion energy and a small angular distribution is crucial for maintaining vertical sidewalls and avoiding profile distortions, such as bowing.

In addition, existing ALE processes often struggle to achieve high synergy between the surface modification and sputtering steps. Ideally, the two steps should complement each other, maximizing the overall etch per cycle (EPC) with minimal unwanted etching from either step. In practice, it is difficult to prevent ions from causing some etching during the surface modification step, while physical sputtering during the removal step may affect unmodified material, reducing the ideality of the ALE process. Karanik et al., in their paper “Predicting synergy in atomic layer etching” (J. Vac. Sci. Technol. A35, 2017), emphasized the importance of minimizing unwanted etching from both steps to maximize process performance.

One approach to mitigating these challenges, as disclosed in U.S. Pat. No. 9,362,131 to Agarwal et al., involves using a remote plasma source combined with an electron beam to minimize ion energy during surface modification. While this method reduces the risk of reactive ion etching (RIE) during surface modification, it requires additional equipment, adding complexity and cost. In light of these challenges, the present invention introduces novel ALE methods and systems to enhance process efficiency and precision, offering a more effective solution for etching HAR structures.

### SUMMARY

In some embodiments, the present invention provides a plasma process system and method designed for ALE processes, particularly suited for HAR structures. The system features a unique chamber design, where the process chamber is divided into an upper chamber and a lower chamber, each serving distinct functions. In some implementations, the upper chamber operates as an inductively coupled plasma (ICP) reactor, generating chemically reactive neutrals or radicals used in the surface modification step, while the lower chamber operates as a capacitively coupled plasma (CCP) reactor for ion-burst sputtering, which removes the modified surface layer. In some embodiments, the lower chamber is used as a radical reactor during the surface modification step.

In some embodiments, the ALE process includes a continuous surface modification step throughout the entire process, during which the substrate surface is exposed to chemically reactive neutrals generated in the upper chamber. Sequential ion-burst sputtering steps are then inserted into the modification step. These sputtering steps are brief but sufficient to remove the modified layer, with pulse durations ranging from 10 to 50 milliseconds to ensure minimal additional surface modification. The surface modification step has a typical duration ranging from 50 to 500 milliseconds, which allows enough time for radicals to react with the surface atoms, particularly at the bottom of HAR structures. This novel design of the ALE process for achieving synergy between the surface modification and sputtering steps prevents unwanted reactive ion etching (RIE) while substantially improving the cycle time of the ALE process.

In some implementations, a tailored waveform generator is utilized during the ion-burst sputtering step to provide precise control over ion energy distribution. The tailored waveform generator produces ions with a tight energy distribution, ensuring efficient material removal while maintaining process precision. Additionally, the tailored waveform generator allows for a rapid establishment of the steady-state voltage bias for the substrate, which helps achieve consistent ion energy for uniform etching.

The steady-state chamber pressures in the upper and lower chambers may differ in some embodiments. For example, due to the design of the grounded ion filter (GIF), which separates the two chambers, the pressure in lower chamber may be lower than that of the upper chamber. This pressure differential is useful in maintaining the ideal conditions for the surface modification and sputtering steps.

In some embodiments, the invention is particularly well-suited for etching HAR structures, such as those found in 3D NAND devices, due to its ability to maintain vertical sidewalls and avoid profile distortions. The combination of a unique chamber design, controlled ion-burst sputtering, and regulated chamber pressures without gas exchanging allows for highly accurate and efficient material removal, making the method and system ideal for advanced semiconductor manufacturing.

### BRIEF DESCRIPTIONS OF DRAWINGS

To enhance clarity, the following description refers to the accompanying drawings:

FIG. 1A: Depicts an exemplary plasma processing chamber, which incorporates a GIF that partitions the chamber into an upper and a lower chamber.

FIG. 1B: Displays a top-view illustration of the GIF, highlighting its design.

FIG. 1C: Offers a detailed view of an exemplary design for the GIF.

FIG. 1D: Illustrates alternative embodiments and designs of the GIF.

FIG. 2: Depicts the waveforms of the plasma source, substrate bias, and gases used in the ALE process.

FIG. 3A: Captures the functionalities of the upper and lower chambers during an ALE process, which includes a surface modification step throughout the process and ion-burst sputtering steps.

FIG. 3B: Shows a schematic diagram of the ALE process applied to ONON etching for 3D NAND channels, with continuous surface modification and intermittent ion-burst sputtering steps.

FIG. 4: Provides a step-by-step flowchart that describes the operation of an ALE process within the exemplary plasma process chamber.

### DETAILED DESCRIPTIONS

This section delves into detailed embodiments of the present invention to ensure a comprehensive understanding. Specific examples are provided for clarity, but it should be understood that modifications and variations that align with the claims are considered within the scope of this invention. Conventional methods and components are discussed where relevant to underscore the distinct features of the invention.

### Definitions

Atomic Layer Etching (ALE): A precise, layer-by-layer material removal process typically used in semiconductor fabrication. ALE involves alternating steps, often surface modification followed by physical removal (such as sputtering), to achieve atomic-level control over material etching. The self-limiting reactions in each cycle ensure high selectivity and precision.

Process Chamber: A sealed environment where manufacturing processes like etching, deposition, or chemical treatments occur. The chamber holds a substrate and maintains controlled conditions, such as vacuum pressure, temperature, and the introduction of gases or plasma to facilitate the process.

Upper Chamber: The upper section of a vacuum chamber, separated by a GIF. It functions as an ICP source.

Lower Chamber: The lower section of a vacuum chamber that operates as a CCP reactor during the sputtering step of the ALE process.

Grounded Ion Filter (GIF): A conductive plate positioned parallel to the substrate that divides the vacuum chamber into upper and lower chambers. The GIF has openings allowing neutrals to pass through and react with the substrate, while blocking ions. During the sputtering step of the ALE process, the GIF acts as the grounded plate of a capacitor.

High Aspect Ratio (HAR) Structures: Structures characterized by a large ratio of height to width (or depth to width), common in advanced microelectronics and semiconductor devices, where vertical etching must be precise to prevent collapse or distortion of deep, narrow features. Surface Modification: A process where the surface of a material is chemically or physically altered to achieve specific characteristics. It involves applying reactive species to form a modified layer that is easier to remove or manipulate in subsequent steps.

Sputtering Step: A process where atoms are ejected from a solid material due to the impact of energetic particles, typically ions. In etching, the sputtering step selectively removes surface layers by ion bombardment.

Neutral: Electrically neutral particles (atoms or molecules) that do not carry a net charge but can still participate in chemical reactions. Neutrals are important in plasma processes because they can diffuse into regions where charged particles cannot.

Chemically Reactive Neutrals or Radicals: Neutral particles capable of reacting with a substrate's surface without carrying a charge. These neutrals modify the surface, making material removal more controlled in subsequent steps.

Ion-Burst: A brief, controlled release of ions directed at a substrate. In ALE processes, ion bursts remove material in short, controlled increments, offering precise control over ion energy and exposure time.

RF Power Generator: A device that generates radio frequency power to energize plasma in semiconductor manufacturing processes, such as etching or deposition.

Bias Unit: A component that generates bias voltage to accelerate ions toward the substrate held by an electrostatic chuck (ESC), creating an electric field essential for controlling ion energy and directionality.

Tailored Waveform Generator: A device that produces custom waveforms, typically used to control the bias applied to a substrate during processing. These waveforms ensure optimal control over etching steps by creating narrow ion energy distributions.

Single Gas or Gas Mixture: A gas or combination of gases used throughout the ALE process, simplifying the process by avoiding gas exchanges, thus improving efficiency.

Gas Source: The origin of process gases used in a vacuum chamber, typically connected to a centralized gas distribution system. The gas source delivers controlled gas flow and composition to ensure proper process conditions.

System Controller: A control unit responsible for coordinating the various components of a process system, managing operations such as plasma generation, gas flow, and substrate biasing.

Plasma Source: A device that generates plasma, a state of matter consisting of charged particles and neutrals, used in manufacturing processes to modify surfaces, etch materials, or deposit films.

Etching Selectivity: The ability of an etching process to preferentially remove one material over another, essential in multi-layer structures to ensure precise removal without damaging other layers.

Reactive Ion Etching (RIE): A plasma-based etching technique combining physical sputtering and chemical reactions to achieve anisotropic etching, commonly used for creating fine, high-precision patterns in semiconductor fabrication.

Fluorine-Containing Gases: Gases that contain fluorine atoms, such as CF₄, SF₆, and C₂F₆, frequently used for etching silicon-based materials due to their high reactivity.

Pulse Train: A sequence of controlled voltage pulses used in processes like etching to modulate ion bombardment timing and energy for precise material removal.

Chamber Pressure: The pressure within a process chamber, which is controlled to optimize plasma generation, etching, or deposition rates.

Substrate Bias: An electrical potential applied to the substrate during processing, controlling ion acceleration toward the substrate for precise material removal.

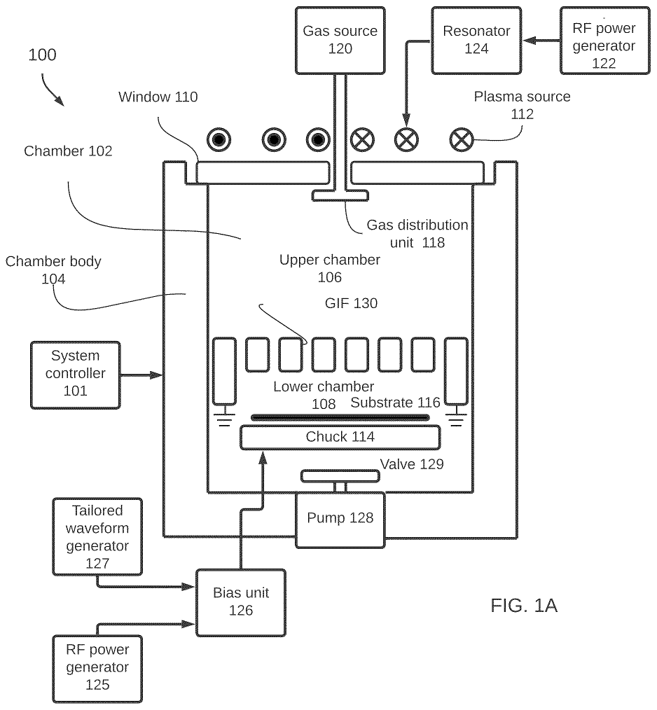

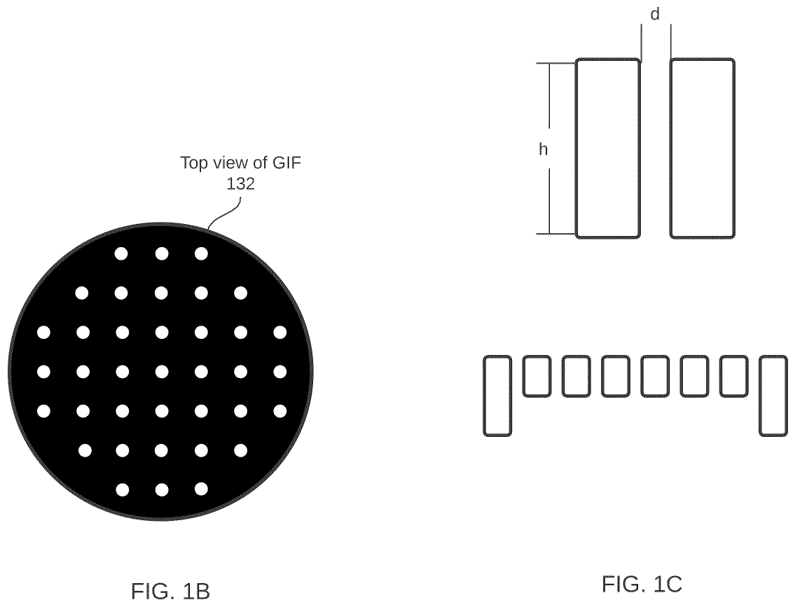

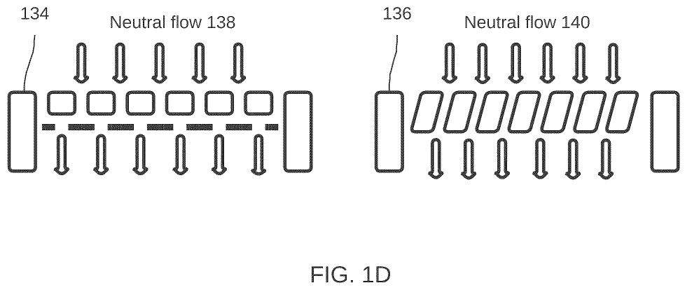

FIG. 1A illustrates an exemplary process system (100) incorporating a plasma process chamber (102). The operations within the chamber (102) are coordinated by a system controller (101). The process chamber (102) is enclosed by a chamber body (104), which creates a vacuum environment conducive to plasma processes. Atop the chamber body (104), a window (110), typically made from a dielectric material such as quartz or ceramic, seals the chamber (102).

Positioned above the window (110) is a plasma source (112), which in FIG. 1A is shown as consisting of a three-turn coil. The coil may have more or fewer than three turns, depending on the specific requirements, and may include multiple coils. Although a flat coil (112) is depicted in FIG. 1A, other configurations such as cylindrical or conical coils can be employed based on the specific implementation.

The plasma source (112) is connected to an RF power generator (122) through a resonator (124). The RF power generator (122) can produce RF power at single or multiple frequencies, including but not limited to 100 kHz, 400 kHz, 2 MHz, and 13.56 MHz. The resonator (124) is used to match the output impedance of the RF generator (122) to the plasma load within the chamber (102), compensating for the effects of transmission lines, as is well known in the art.

As shown in FIG. 1A, a gas distribution unit (118) connects to a gas source (120) through an opening in the window (110). Proper sealing of this opening is essential to maintain the vacuum environment within the chamber (102). The gas distribution unit (118) may take the form of an injector or a showerhead, depending on the specific implementation. In some variations, the window (110) itself may serve as a combined gas distribution unit and showerhead, maintaining the seal for the vacuum chamber from above. Additionally, in some embodiments, the gas distribution unit (118) may include side-injection mechanisms to introduce gas into the chamber (102) from its sides. The system also includes a pump (128) and a valve (129) for evacuating unused gases and byproducts from the chamber (102).

Within the chamber (102), a chuck (114) is used to support a substrate (116). The chuck (114) can be an electrostatic chuck (ESC) or a vacuum chuck, depending on the specific implementation.

The chamber (102) is divided into an upper chamber (106) and a lower chamber (108) by a GIF (130). The GIF (130) is positioned parallel to the substrate (116) and is made from conductive materials such as aluminum or silicon. The aluminum may be anodized to enhance erosion resistance. The GIF (130) can be grounded through the chamber body (104) or via other grounded structures within the chamber (102), such as liners (not shown).

The upper chamber (106) functions as an ICP reactor throughout the ALE process. When plasma is ignited within the upper chamber (106), electrons, ions, and neutrals are generated. The GIF (130) acts as a barrier, blocking ions while allowing neutrals and unreacted gases to pass through the openings in the GIF (130). FIG. 1B provides a top-view illustration of the GIF (130), highlighting an exemplary opening (132). In FIG. 1C, each opening has a diameter (d) and height (h). To effectively block ions, the diameter must be small, and the aspect ratio (h/d) must be substantial. The height of the openings may range from 0.1 mm to 10 mm, with aspect ratios spanning from 10 to 500.

Several implementations of the GIF (130) are possible. FIG. 1D illustrates two examples. In the first example (134), the GIF (130) consists of a first group of vertical holes, a horizontal conducting channel connected to the holes in the first group, and a second group of vertical holes linked to the horizontal channel. The holes in the second group are intentionally misaligned with those in the first group, ensuring complete ion blocking while allowing neutral flow (138) through the GIF (130). In the second example (136), the openings in the GIF (130) are angled relative to the vertical direction of the GIF surface. This arrangement prevents ions from passing through the openings while allowing neutral flow (140) to diffuse through.

These designs are illustrative, and numerous variations can achieve the functionalities of the GIF (130). The openings do not have to be circular; they can be of various shapes, such as square, rectangular, elliptical, hexagonal, or octagonal. Additionally, the sizes and depths of the openings may vary, and their distribution can be either uniform or non-uniform. The GIF (130) may have varying thicknesses, and multiple ion-blocking methods can be utilized. For instance, more than one horizontal conducting channel may be combined with angled openings. These variations are all within the scope of the present invention.

Returning to FIG. 1A, during operation, the upper chamber (106) functions as an ICP chamber. After plasma ignition, electrons diffuse toward the GIF (130) and the chamber body (104). Since the GIF (130) is grounded and lacks a blocking capacitor, the plasma sheath on its surface is negligible. This feature extends its operational lifetime and minimizes ion bombardment on the GIF surface.

The lower chamber (108) operates as a radical reactor for surface modification and a CCP reactor for sputtering. When the lower chamber (108) is operated as the CCP reactor, the GIF (130) is utilized as the grounded electrode and the chuck (114) functioning as the powered electrode. In one implementation, the chuck (114) receives RF power at a predetermined frequency from a bias unit (126). The bias unit (126) includes an RF power generator (125). The frequency can range from 100 kHz to 100 MHz. In another implementation, the RF power generator (125) delivers RF power at multiple frequencies, including but not limited to 100 kHz, 400 kHz, 1 MHz, 2 MHz, 13.56 MHz, and 60 MHz. The bias unit (126) establishes a bias on the chuck (114) and can ignite plasma in the lower chamber (108) between the two electrodes. Typically, plasma density in a CCP reactor is lower than that in an ICP reactor but increasing the RF frequency from the RF power generator (125) enhances plasma density in the lower chamber (108). The bias unit (126) also increases the plasma sheath thickness to accelerate ions toward the substrate (116).

In another implementation, the bias unit (126) further includes a tailored waveform generator (127), which delivers tighter ion energy distribution, allowing for more precise ion bombardment during the sputtering step. The tailored waveform generator (127) can create a steady-state substrate bias in a range of microseconds which is critically important for ion-burst sputtering step which can minimize additional surface modification during the step.

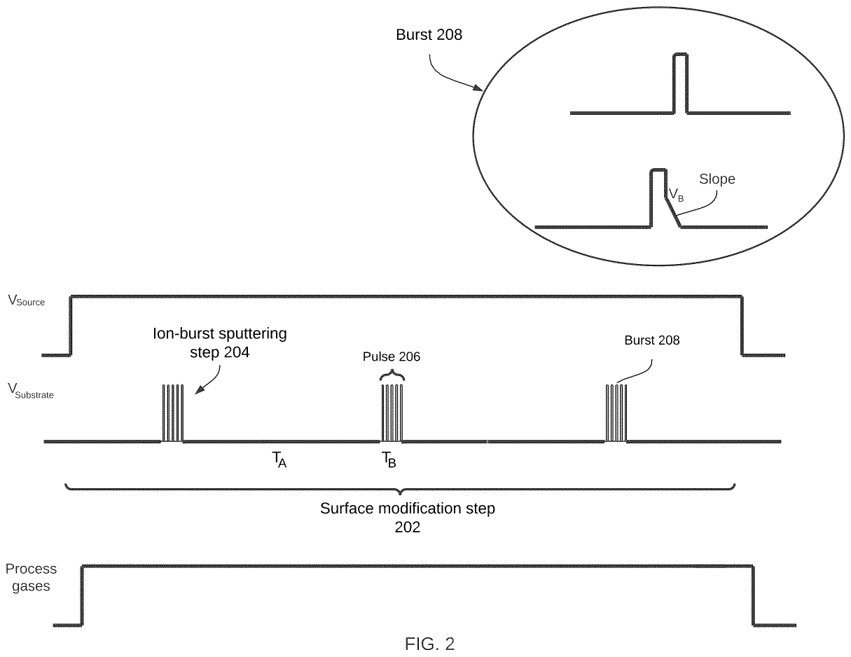

FIG. 2 illustrates exemplary waveforms for an embodiment where a single process gas or gas mixture is injected from the gas distribution unit (118). The flow of the gas or gas mixture is depicted at the bottom of FIG. 2. In this embodiment, the same gas or gas mixture is utilized throughout the entire ALE process without the need for gas exchanges, significantly improving the ALE cycle time. Once the gas or gas mixture is introduced, the system controller (101), based on the measured chamber pressure, employs a proportional-integral-derivative (PID) control to establish a steady-state pressure in the chamber. In one implementation, a manometer (not shown in the figure) is installed in the upper chamber (106). Depending on the design of the GIF (130), the steady-state pressure in the lower chamber (108) may either match or be lower than the pressure in the upper chamber (106). If gas conductance through the GIF (130) is a limiting factor, the pressure in the lower chamber (108) will be lower.

In one implementation, a constant RF power is applied to the plasma source (112), represented as V_{Source} in FIG. 2. The power delivered to the plasma source (112) is a function of the voltage, current, and phase difference between the two. In another implementation, the RF power may be pulsed with a duty cycle ranging from 1% to 50%.

The plasma source (112) receives the RF power and generates plasma within the chamber (102). The plasma consists of electrons, ions, and neutrals. Neutrals and unreacted gases diffuse from the upper chamber (106) into the lower chamber (108).

In an alternative implementation, the chamber pressure may be controlled by a manometer installed in the lower chamber (108). The system controller (101) then utilizes the measured lower chamber pressure to regulate steady-state pressures using PID control.

In a preferred embodiment, a tailored waveform generator (127) is utilized in conjunction with RF power generators (125) as part of the bias unit (126). The RF power generator (127) generates a second plasma in the lower chamber (108), which provides the ions to remove the modified layer created by radicals that have diffused from the upper chamber (106).

The bias applied to the substrate (116) is represented as V_{Substrate} in FIG. 2. The novel ALE process disclosed includes a continuous surface modification step (202) throughout the process, with intermittent ion-burst sputtering steps (204) inserted into the surface modification step. The sputtering step (204) is characterized by a pulse (206), which includes sequential voltage bursts (208)—brief, high-voltage biases generated by the tailored waveform generator. These voltage bursts accelerate ions, allowing them to remove the surface layer modified between consecutive pulses.

At the top-right of FIG. 2, operation of the tailored waveform generator (127) is elaborated. The output from the tailored waveform generator begins with a brief positive voltage spike, which neutralizes any trapped positive charges by attracting electrons onto the substrate. This is followed by a negative bias V_{B}, which ramps down to a more negative voltage, compensating for trapped positive charges from ions. This ramp ensures a constant substrate bias V_{Substrate} for ion acceleration during each ion-burst event.

The duration between two consecutive pulses for surface modification is denoted as T_{A}, while the pulse duration for the ion-burst sputtering step is denoted as T_{B}. In the ALE process, the gap between the gas distribution unit (112) and the chuck (114) typically ranges from 3 to 30 centimeters. It takes approximately 20 to 200 milliseconds for neutrals to diffuse from near the plasma source to the substrate (116) held by the chuck (114). According to Karanik et al. in “Atomic Layer Etching: Rethinking the Art of Etch” (J. Phys. Chem Lett. vol. 9, 2018, pp. 4814-4821), surface reactions may take milliseconds to complete. An additional 30 to 300 milliseconds may be required for neutrals to reach and react with the surface, particularly at the bottom of HAR structures. Consequently, T_{A} is typically set between 50 and 500 milliseconds, depending on the chamber volume, plasma density, and the aspect ratio of the structure, while T_{B} is typically set between 10 and 50 milliseconds to ensure sufficient ion flux to remove the modified layer without further surface modification during the ion-burst sputtering.

In this embodiment, surface modification continues in the background, and the substrate (116) does not need to wait for radicals to reach its surface. For etching a HAR structure, the required time for the radicals to diffuse into the etch front may differ at different stages of the process. A unique feature of the present inventive concept is to vary T_{A} as a function of the processing time. For example, T_{A} may be progressively increased to reflect the depth dependent diffusion time of the radicals.

Additionally, the pulse duration for the sputtering step depends on the ion flux and yield, which are functions of ion energy. To reduce the pulse duration, either ion density or ion energy can be increased. The novel ALE process disclosed herein employs high ion density and energy to reduce the ion exposure time. The short sputtering time minimizes the likelihood of the surface being re-modified during sputtering, thereby reducing unwanted reactive ion etching (RIE) effects during the sputtering step.

Another unique feature of the present inventive concept is to design the ion energy as a function of the processing time. At early cycles of the process, relatively lower ion energy can be used. As the etch front is pushed down through the etching, the ion energy can be increased progressively to tailor the increased aspect ratio of the structures.

In FIG. 2, a constant RF power is illustrated throughout the ALE process. The RF power includes at least one frequency in the range of 100 kHz to 60 MHz, and the power level is in the range of 50 to 5000 watts. The RF power can be switched on and off at a predetermined frequency, ranging from 100 Hz to 100 kHz, with a duty cycle of 1% to 50%. The RF power applied during the sputtering step may differ from that during the surface modification process. In some cases, different RF power levels may be applied during the sputtering step.

The precise RF power and timing parameters can be determined through an ALE process simulator, taking into account factors such as gas flow, chamber size, and structure aspect ratios. Alternatively, the parameters may be optimized using design of experiments (DOE) methodologies.

Since a single gas or gas mixture is used throughout the ALE process, careful design of the chamber pressure is critical. Higher pressure can reduce surface modification time and increase ion density during the sputtering step, but it can also broaden ion angular distribution, which may affect profile accuracy. Ideal chamber pressure ranges from 1 mTorr to 500 mTorr, depending on the specific application. In this embodiment, the pressure in the upper chamber (106) and lower chamber (108) may differ. For example, the conductance of the channels in the GIF (130) can be designed to create a lower pressure in the lower chamber (108).

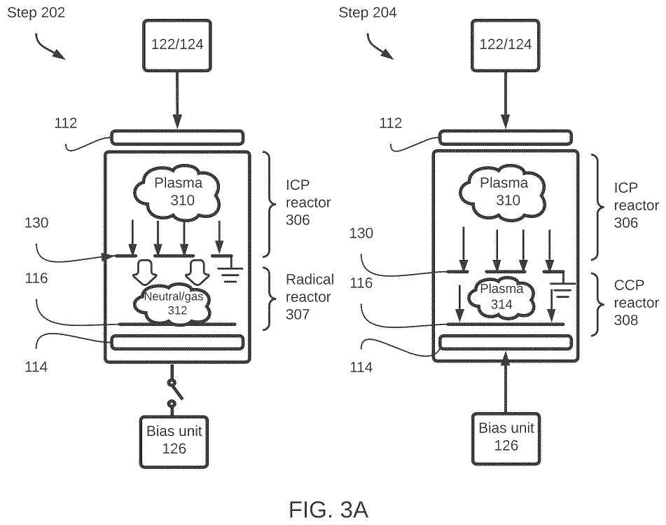

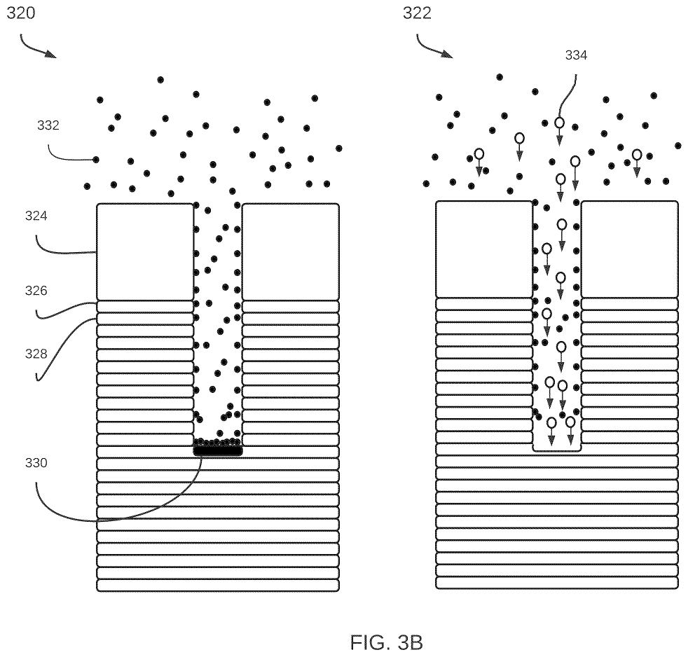

FIG. 3A illustrates the functionalities of the upper and lower chambers during an ALE process, which includes a surface modification step (202) throughout the entire ALE process, intercepted by intermittent ion-burst sputtering steps (204). During the modification step (202), the upper chamber (106) operates as an ICP reactor (306), and the lower chamber (108) functions as a radical reactor (307). The plasma source (112) receives RF power from the RF power generator (122) through the resonator (124) and generates plasma (310) in the upper chamber (106). The plasma (310) contains electrons, ions, and neutrals, which includes chemically reactive parts: radicals. The ions are blocked by the GIF (130), while neutrals and unreacted gases diffuse into the lower chamber (108), forming a neutral/gas cloud (312) in the radical reactor (307).

The bias unit (126) is deactivated during the period for modifying the substrate surface, defined by two consecutive ion-burst sputtering steps. This modification results in the formation of one or a few monolayers on the surface, which exhibit weaker chemical bonds.

FIG. 3B depicts the application of the ALE process for etching an oxide-nitride-oxide-nitride (ONON) stack to form channel holes in 3D NAND devices. The structure undergoing the surface modification is labeled as (320) and the structure undergoing the ion-burst sputtering as (322).

The hard mask is denoted as (324), while the oxide layer and nitride layer are labeled as (326) and (328), respectively. A modified layer (330) forms at the bottom of the structure due to reactions between surface atoms and chemically reactive neutrals (332). For example, fluorine-containing reactive neutrals may diffuse to the etch front, reacting with surface atoms to weaken bonds in the modified layer.

The modification step (202) is self-limiting and reaches saturation once the surface has been exposed to the neutrals including the radicals for a sufficiently long period. To maintain the ideal conditions for the ALE process, it is crucial to avoid ion bombardment during step (202), as energetic ions can induce RIE, thereby detracting from an ideal ALE process. The GIF (130) blocks ions during the surface modification and improve synergy of the ALE process.

During the ion-burst sputtering step (204), gases in the lower chamber (108) is excited by the RF power generator in the bias unit (126) to form a plasma (314). The lower chamber is functioning as a CCP reactor (308) with the chuck (114) as the powered electrode and the GIF (130) as the ground. Positive ions like argon ions are then accelerated by a sheath electrical field, which facilitates the removal of the modified surface layer. To avoid additional surface modification during the step (204), the tailored waveform generator is used to generate ion-bursts to remove swiftly the modified layer. When the tailored waveform generator provides burst voltage biases to the chuck (114) and hence substrate (116), ions (334) are accelerated towards the etch front to sputter away the modified layer. It is essential that the ions have a small angular distribution to maintain vertical profiles for the structure's sidewalls. The timing of the sputtering step requires careful design to be long enough to deploy enough ions to remove the modified layer but sufficiently short to minimize addition surface modification. Once this layer is removed, the physical sputtering of the substrate's surface typically slows down. Like the modification step (202), the sputtering step (204) also exhibits self-limiting characteristics.

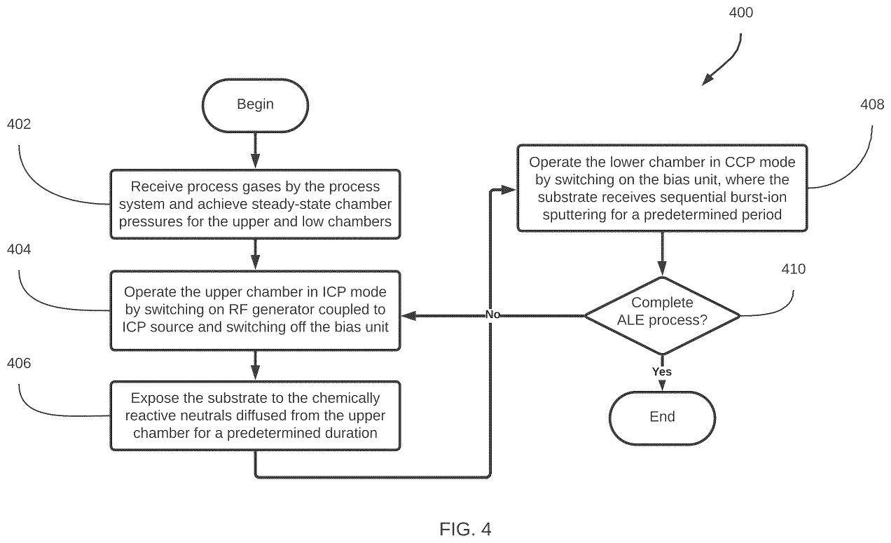

FIG. 4 outlines an exemplary ALE process according to an embodiment of the present invention, labeled as 400. The process begins with step 402, where the system controller (101) introduces a single gas or gas mixture into the upper chamber (106) via the gas distribution unit (118). For example, fluorine-containing gases mixed with argon may be injected. The system controller (101) uses a PID control to establish steady-state pressures for the upper chamber (106) and the lower chamber (108). The pressure of the lower chamber (108) maybe at lower level than the pressure in the upper chamber (106).

In step 404, the system controller (101) operates the upper chamber (106) as the ICP reactor (306), where the plasma source (112) receives the RF power from the RF power generator (122) via the resonator (124). This power may consist of one or more frequencies between 100 kHz and 60 MHz, with power levels from 50 to 5000 watts. The RF power may be pulsed at a frequency of 100 Hz to 100 kHz with a duty cycle of 1% to 50%, or it may remain constant throughout the modification step. The bias unit (126) is deactivated. The lower chamber (108) is used as a radical reactor (307) for modifying the substrate surface to form the modified layer.

In step 406, the substrate (116) is exposed to the radicals for a predetermined duration T_{A}ranging from 50 to 500 milliseconds.

In step 408, the chuck (114) is connected to the bias unit (126) to operate the lower chamber (108) as the CCP reactor (308). The RF power generator (125) in the bias unit (126) generates the plasma (314) in the lower chamber using the chuck (126) as the powered electrode and the GIF (130) as the ground. The ions in the plasma (314) are accelerated by voltage burst generated by the tailored waveform generator (127) to remove the modified layer. The pulse (206)) duration is designed to be in a range between 10 to 50 milliseconds to avoid the additional surface modification while operating the lower chamber (108) as the CCP reactor (308). During the pulse, sequential ion-bursts are generated, ensures that ions, accelerated by the substrate bias, remove the modified layer without giving radicals enough time to cause further surface modification. The substrate bias may range from 100 to 10,000 volts.

Finally, in step 410, the system controller 101 checks whether all ALE cycles are complete. If not, the steps 404 to 410 are repeated.

1. A plasma process chamber configured for ALE, the chamber comprising:
an upper chamber and a lower chamber separated by a GIF, wherein the upper chamber includes an ICP source, and the lower chamber includes a chuck operatively coupled to a bias unit including an RF power generator and a tailored waveform generator; and
a system controller configured to execute an ALE process comprising a surface modification step throughout the process and a plurality of ion-burst sputtering steps inserted into the modification step,
wherein, during the modification step, the chamber operated by the system controller is configured to:
initiate a plasma comprising electrons, ions and neutrals in the upper chamber by supplying RF power from a RF power generator to the ICP source,
prevent the ions from entering the lower chamber by the GIF, and
permit neutrals and unreacted gases to pass through openings in the GIF, wherein the lower chamber is operated as a radical reactor to modify a surface of a substrate to form a modified layer, wherein the substrate is held by the chuck without applying a bias to the substrate,
wherein, during the ion-burst sputtering step, the chamber operated by the system controller is configured to:
generate a plasma in the lower chamber by operating the lower chamber as a CCP reactor, using the chuck and the GIF as electrodes, wherein the chuck is connected to the RF power generator within the bias unit, and
generate sequential voltage bursts by the tailored waveform generator to accelerate ions in the lower chamber to remove the modified layer.

2. The chamber of claim 1, wherein a single gas or gas mixture is introduced into the chamber via a gas distribution unit throughout the ALE process without gas exchange during the process.

3. The chamber of claim 1, wherein a steady-state chamber pressure is established by the system controller through a manometer placed in the upper chamber or in the lower chamber.

4. The chamber of claim 1, wherein the lower chamber is at lower pressure than the upper chamber, wherein the lower chamber pressure is enabled by designing gas conductance of the openings of the GIF.

5. The chamber of claim 1, wherein the openings in the GIF are dimensioned and configured such that the leakage of ions through the openings is negligible.

6. The chamber of claim 1, wherein the openings in the GIF are oriented at an angle relative to the vertical direction with reference to the substrate surface.

7. The chamber of claim 1, wherein the openings in the GIF comprise a first group of openings, a horizontal conducting channel connected to the first group of the openings and a second group of openings connected by the horizontal conducting channels, wherein the openings in the second group are misaligned from the openings in the first group.

8. The chamber of claim 1, wherein the system controller defines an interval between the two consecutive sputtering steps with a duration ranging from 50 to 500 milliseconds and defines the duration of the sputtering step ranging from 10 to 50 milliseconds.

9. The chamber of claim 1, wherein the system controller utilizes an ALE process simulator to determine an interval between two consecutive sputtering steps and the duration of the sputtering step, such that the substrate surface is sufficiently modified during the interval, while the surface modification within the sputtering step is minimized.

10. The chamber of claim 8, wherein the interval is progressively increased as the ALE process is progressing.

11. The chamber of claim 1, wherein the tailored waveform generator provides voltage biases for the substrate in a range from 100 to 10,000 volts during the sputtering step.

12. The chamber of claim 11, wherein the voltage bias is progressively increased as the ALE process is progressing.

13. The chamber of claim 1, wherein the plasma source is further configured to receive RF power from the RF power generator with pulsing at a predetermined frequency ranging from 100 Hz to 100 kHz, and at a duty cycle from 1% to 50% during the surface modification step.

14. A method for performing an ALE process on a substrate, the method comprising:
placing the substrate on a chuck situated within a plasma process chamber, the chamber being divided into an upper chamber and a lower chamber by a GIF;
conducting a surface modification step throughout the process for modifying the surface of the substrate, the surface modification step comprising:
introducing a single process gas or gas mixture from a gas source into the upper chamber via a gas distribution unit;
igniting a plasma comprising electrons, ions, and neutrals within the upper chamber by applying RF power to an ICP source positioned atop the upper chamber while a bias unit for chuck is deactivated;
exposing the substrate to neutrals diffused from the upper chamber to the lower chamber through a plurality of openings in the GIF, with the ions being obstructed by the GIF;
conducting an ion-burst sputtering step at a predetermined insertion point of the modification step, comprising:
activating the bias unit and operating the lower chamber as a CCP reactor;
igniting a plasma including at least an inert gas comprising electrons, ions, and neutrals within the lower chamber by the RF power generator in the bias unit, wherein the inert gas is diffused from the upper chamber through the openings in the GIF;
generating sequential voltage bursts to accelerate ions in the lower chamber;
exposing the substrate to the plasma for a predetermined duration to remove the modified surface of the substrate; and
repeating the sputtering steps until the ALE process is completed, wherein an interval between two consecutive sputtering step is determined by the system controller.

15. The method of claim 14, further comprising a step for establishing a steady-state upper chamber pressure by the system controller using a manometer installed in the upper chamber.

16. The method of claim 14, further comprising a step for establishing a steady-state lower chamber pressure by the system controller using a manometer installed in the lower chamber.

17. The chamber of claim 14, wherein the system controller defines an interval between the two consecutive ion-burst sputtering steps with a duration ranging from 50 to 500 milliseconds and defines the duration of the ion-burst sputtering step ranging from 10 to 50 milliseconds.

18. A process system, comprising:
a plasma process chamber defined by a chamber body;
a GIF dividing the chamber into an upper chamber and a lower chamber, wherein the upper chamber is further defined by a window and the GIF, and the lower chamber is further defined by the GIF and a chuck, with the GIF being a conductive material featuring a plurality of openings that allow neutrals and unreacted gases to migrate from the upper chamber to the lower chamber while obstructing ions from entering the lower chamber from the upper chamber;
an ICP source connected to an RF power generator to produce a first plasma in the upper chamber, functioning as an ICP reactor;
a second RF power generator linked to the chuck to create a second plasma in the lower chamber, operating as a CCP reactor; and
a tailored waveform generator for generating a pulse including a plurality of sequential voltage bursts for the substrate to accelerate ions in the lower chamber.

19. The chamber of claim 18, wherein the GIF is grounded through a liner of the chamber body.

20. The chamber of claim 18, wherein the openings in the GIF are dimensioned and configured such that the leakage of ions through the openings is negligible.
